(19) United States
(12) Patent Application Publication
(10) Pub. No.: US 2025/0139342 A1
(43) Pub. Date: May 1, 2025

(54) SAMPLE SYNTHESIS USING AN AI DIGITAL TWIN

(71) Applicant: Advanced Micro Devices, Inc., Santa Clara, CA (US)

(72) Inventors: Arun Kumar CHANDRAN, Singapore (SG); Yao Cui FEHLIS, New Braunfels, TX (US)

(21) Appl. No.: 18/499,026

(22) Filed: Oct. 31, 2023

(51) Int. Cl. G06F 30/3308

(52) U.S. Cl. CPC G06F 30/3308

(57) ABSTRACT

Embodiments herein use constraints from a target process (e.g., testing a semiconductor wafer or designing a new integrated circuit) and historical real-world samples (e.g., probe test sample, fault detection, or measured signals) to generate synthesized samples using AI synthesis embedded in a digital twin. These test samples can be combined with real-world test samples and then evaluated to determine next actions. In another example, a digital twin can use an new IC design and a design from an older, but related, IC to synthesize new IC design samples.

### TECHNICAL FIELD

Examples of the present disclosure generally relate to generating synthesized samples using artificial intelligence (AI) synthesis in a digital twin.

### BACKGROUND

Data insufficiency is a key problem in many semiconductor manufacturing process improvement tasks. Individual data generation AI methods, such as generative methods and data augmentation can only address data insufficiency problems for specific scenarios. These AI methods are mostly employed for solving data insufficiency problems or a design exploration problems for specific standalone issues such as SEM images for curvilinear masks. As such, these methods are not suitable for system level problems where there are multiple processes which interact with each other.

### SUMMARY

One embodiment described herein is a method that includes receiving, at a computing system, physics constraints related to a real-world process; receiving, at the computing system, historical samples corresponding to previous iterations of the real-world process; performing, using a digital twin at the computing system, artificial intelligence (AI) synthesis to generate synthesized samples for the real-world process based on the physics constraints and the historical samples; performing the real-world process to generate real-world samples; and combining the synthesized samples with the real-world samples.

One embodiment described herein is a computer readable medium comprising instructions which, when executed by a processor in a computing system, perform an operation. The operation includes receiving, at the computing system, physics constraints related to a real-world process; receiving, at the computing system, historical samples corresponding to previous iterations of the real-world process; performing, using a digital twin at the computing system, AI synthesis to generate synthesized samples for the real-world process based on the physics constraints and the historical samples; performing the real-world process to generate real-world samples; and combining the synthesized samples with the real-world samples.

One embodiment described herein is a method that includes receiving, at a computing system, faults identified on a first integrated circuit (IC); receiving, at the computing system, an IC design for a new IC; performing, using a digital twin at the computing system, artificial intelligence (AI) synthesis to generate synthesized design samples for the new IC based on the identified faults and the IC design.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates a workflow for synthesizing samples using a digital twin, according to an example.

FIG. 2 is a flowchart for synthesizing samples, according to an example.

FIG. 3 illustrates a workflow for synthesizing samples using a digital twin to combine with real-world samples, according to an example.

FIG. 4 is a flowchart for synthesizing samples using a digital twin for testing semiconductor wafers, according to an example.

FIG. 5 illustrates a workflow for synthesizing samples using a digital twin to combine with real-world samples, according to an example.

FIG. 6 illustrates a workflow for synthesizing design samples using a digital twin to design an integrated circuit, according to an example.

FIG. 7 is a flowchart for synthesizing design samples using a digital twin to design an integrated circuit, according to an example.

FIG. 8 illustrates a workflow for synthesizing samples using a digital twin using data from multiple domains, according to an example.

FIG. 9 is a flowchart for synthesizing samples using a digital twin using data from multiple domains, according to an example.

FIG. 10 illustrates a workflow for synthesizing samples using a digital twin using data from multiple domains, according to an example.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the embodiments herein or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Embodiments herein use constraints from a target process (e.g., testing a semiconductor wafer or designing a new integrated circuit) and historical real-world samples (e.g., probe test samples, fault detection, or measured signals) to generate synthesized samples using AI synthesis embedded in a digital twin. For example, instead of testing an entire semiconductor wafer, the digital twin of the semiconductor wafer can generate synthesized test samples. These test samples can be combined with real-world test samples and then evaluated to predict whether the semiconductor wafer includes a fault. In another example, a digital twin can use an new IC design and a design from an older, but related, IC to synthesize new IC design samples. Advantageously, using synthesized samples from a digital twin can save time (e.g., reduce the amount of real-world testing that has to occur) and costs (e.g., reduce the number of IC variants that have to be manufactured).

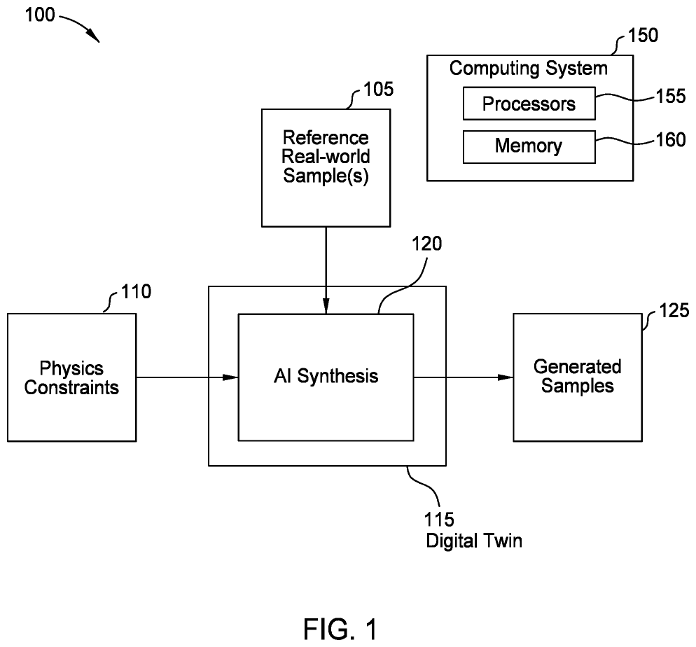

FIG. 1 illustrates a workflow 100 for synthesizing samples using a digital twin, according to an example. The workflow 100 includes a digital twin 115 (e.g., a software application) that performs AI synthesis 120 to generate samples 125. The types of AI synthesis 120 can include signal data (e.g., voltage or current profiles), image data (e.g., scanning electron microscope (SEM) images of a semiconductor wafer or integrated circuit (IC) packages on a substrate), images of signal data (e.g., signal probing at discretized points on a wafer that is visualized as a spatial distribution), or design data (e.g., metal density spatial distribution). The generated samples 125 can include design samples used to manufacture an IC, test signal samples used to determine if a wafer has a fault, failure samples, or a set of parameters which define a manufacturing lifecycle.

In this example, the AI synthesis 120 uses both real-world samples 105 and physics constraints 110 to generate the samples 125. In one embodiment, the real-world samples 105 include historical data, which can include historical fault data, historical test data (e.g., from previously tested semiconductor wafers), or design data from previous IC designs. The reference real-world samples 105 not only serve as a good starting point (to address the cold start problem in synthesis) but also guides the synthesis to generate data samples 125 which have feature distributions similar to them—e.g., wafer substrate spatial distributions which have relative component placement locations similar to real-world samples 105. In one embodiment, historical real-world samples from the past products/manufacturing lifecycle are also considered as reference real-world samples 105. These historical samples can be compared against the reference real-world samples to select relevant historical samples to use for AI synthesis 120.

The physics constraints 110 can limit the synthesis of data samples to guide the synthesis towards feasible samples 125. The physics constraints can include geometry constraints or electrical signal constraints. In general, the constraints 110 can include any type of physical constraints used in testing, design, or modeling a device (e.g., a semiconductor device or an electronic device).

FIG. 1 also illustrates a computing system 150 which includes one or more processors 155 and memory 160. The computing system 150 can be a single computing device (e.g., a server or desktop computer) or network of computing devices (e.g., a data center or cloud computing environment). The processors 155 can have any number of processing cores, and the memory 160 can include volatile memory elements, non-volatile memory elements, and combinations thereof.

In one embodiment, the computing system 150 executes the workflow 100. That is, the physics constraints 110, the real-world samples 105, and the generated samples 125 can be stored in the memory 160. The processors 155 can then execute the AI synthesis 120 in the digital twin 115 to generate the samples 125 using the real-world samples 105 and the physics constraints 110 as inputs. The processors 155 can be general purpose processors (e.g., CPUs) or specialized application specific integrated circuits (ASICs) designed to perform AI synthesis 120.

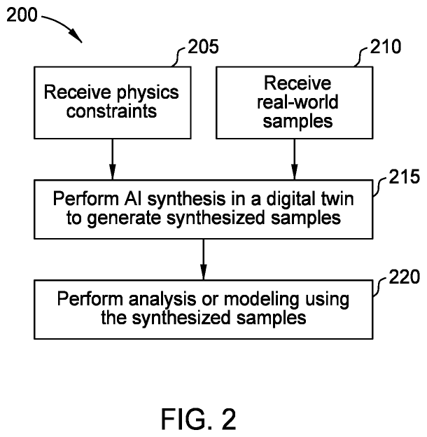

FIG. 2 is a flowchart of a method 200 for synthesizing samples, according to an example. At block 205, the digital twin receives physics constraints. The physics constraints can include geometry constraints or electrical signal constraints. For example, the physics constraints can be testing parameters used to perform a wafer test to identify faults. In another example, the physics constraints can be an IC design, which can include geometric constraints, voltage constraints, current constraints, and the like.

At block 210, the digital twin receives real-world samples. In one embodiment, the real-world samples are historical samples from a the target process. For example, the real-world samples may be historical testing data, or a design from a previous IC.

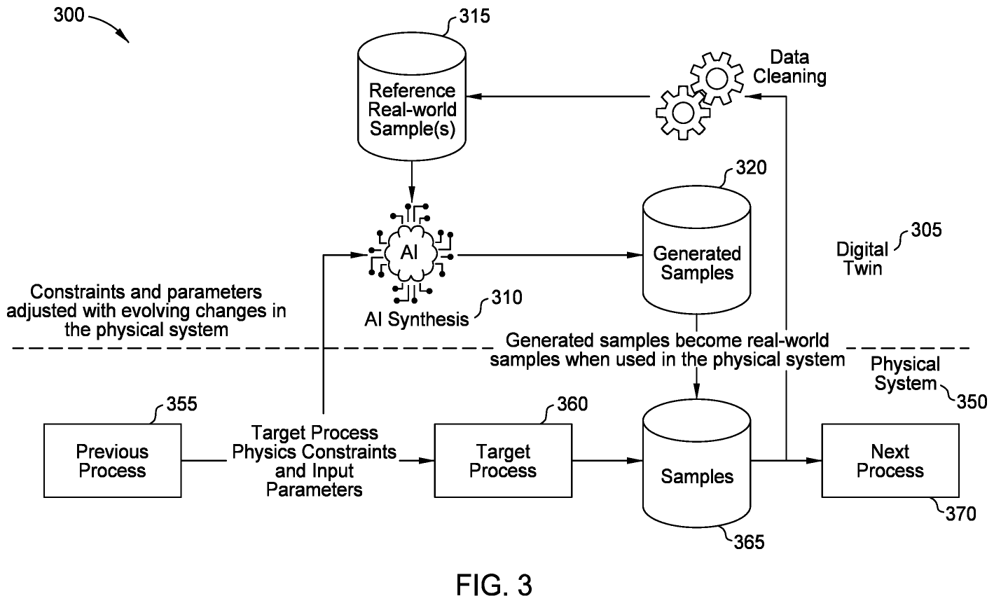

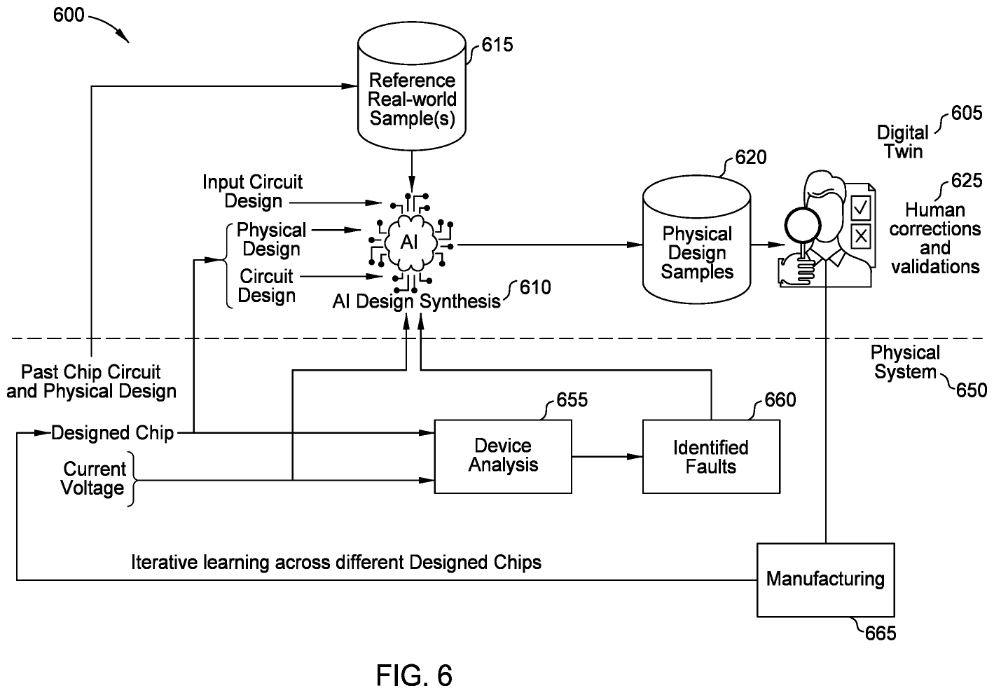

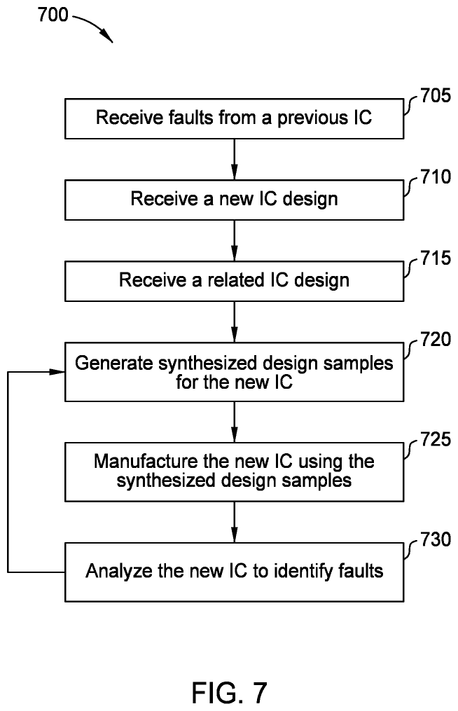

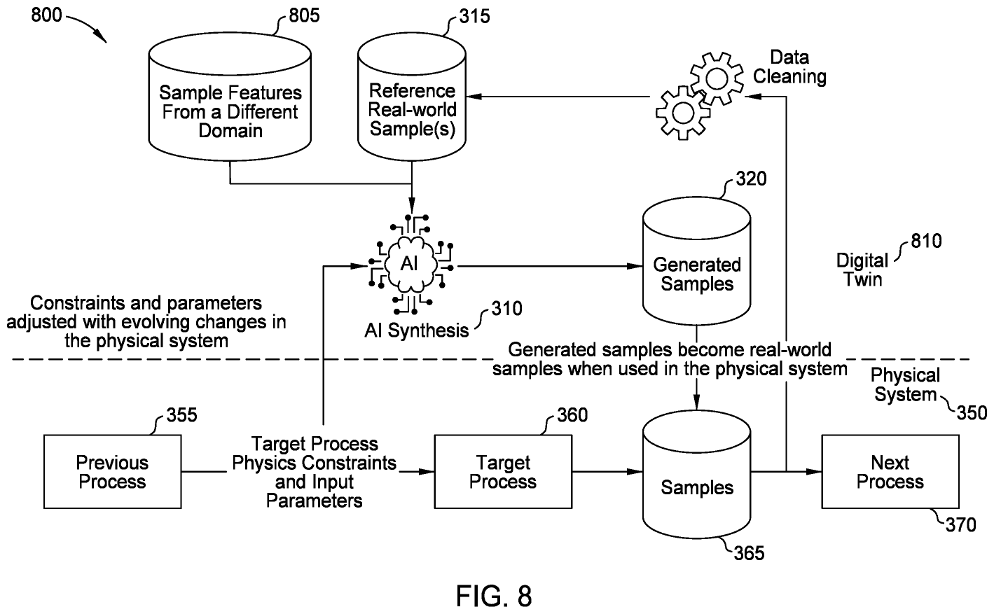

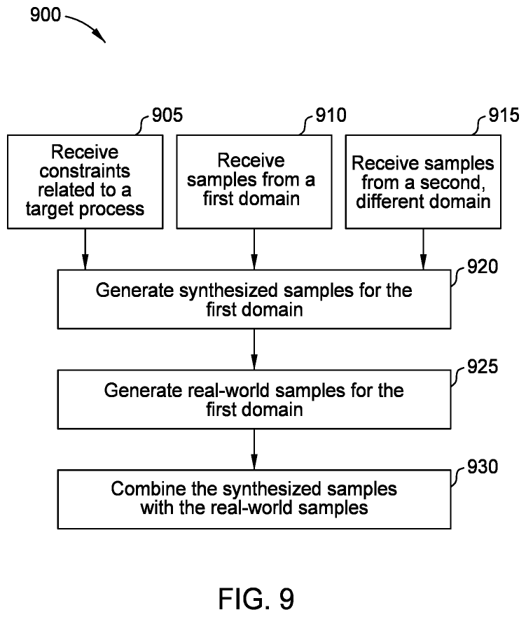

At block 215, the digital twin performs AI synthesis to generate synthesized samples. In one embodiment, the synthesized samples are used to supplemental actual samples. Examples of this are discussed in FIGS. 3-5. In another embodiment, the synthesized samples are used to generate a design of an IC. Examples of this are discussed in FIGS. 6-7. In yet another example, the synthesized samples are in a first domain but were generated using data from a different domain. For example, fault data (e.g., a first domain) can be used to synthesize samples of mask images (e.g., a second domain). Examples of this are discussed in FIGS. 8-9.

Generative adversarial networks and variational autoencoders could be used as the backbone for sample AI synthesis and can cover a wide range of datatypes. Such methods learn complex feature distributions (such as in images, multi-dimensional signals, etc.) much faster than traditional generative methods such as Monte Carlo methods to generate samples. Generative adversarial networks and variational autoencoders are better at handling unlabeled data issues and are well suited to generate samples in image domains too. Design optimization problems and multiple-design requirements could be modeled as a multi-dimensional data sample synthesis, thereby generating samples faster as well as implicitly capturing the relationships between features.

For data samples that are one parameter (or a few parameters) in dimension, traditional optimization methods based on loss functions could be employed to generate samples with noise perturbation to create variety in the samples. Physics informed neural networks can guide the samples synthesis within physics constraints received at block 205 and thereby avoid unrealistic samples which reduce the quality of the samples. Design synthesis problems are well suited to Genetic algorithms (such as Particle Swarm Optimization) and mutation algorithms which embed randomness generation for creating a variety of samples. However, these are iterative algorithms which may take numerous iterations to generate satisfactory performance.

In many cases, AI methods improve the quality of the samples synthesized or generate new insights based on the samples synthesized. Such insights become the feedback to the real-world physical system to affect changes in the manufacturing processes. For example, to reduce the defects in future manufacturing lifecycles by improving manufacturing process(es), a prediction method on expected defects based on past faults and user changing design requirements and/or set point parameters can be used. Such methods could be traditional techniques such as a Decision tree, linear regression (for textual or signal data), or a sophisticated technique such as deep learning neural network with an attention mechanism (for spatial image data) and Long Short-Term Memory (LSTM) layers (in the case of temporal domain information critical). Multi-modal AI techniques which take multiple data streams that are not necessarily in the same domain are effective in jointly learning the variations.

At block 220, analysis or modeling is performed using the synthesize samples. For example, the synthesized test samples can be combined with actual test samples to predict whether a wafer has faults. If so, the wafer may be subjected to further testing. However, if the combined synthesized and actual test samples predict the wafer does not have faults, it can skip the additional test. This is described in FIGS. 3-6.

In another example, synthesized design samples can be used to generate a design or model of an IC. This design (and several variants) can be fabricated. These wafers can then be tested where the results are used in a feedback loop to prompt the digital twin to generate updated synthesized design samples. This is described in FIGS. 7 and 8.

FIG. 3 illustrates a workflow 300 for synthesizing samples using a digital twin 305 to combine with real-world samples, according to an example. In this example, the workflow 300 is divided into the digital twin 305 and a physical system 350, where the digital twin 305 includes the components and data above the dotted line and the physical system 350 includes the components and data below the dotted line.

As shown, the digital twin 305 includes reference real-world samples 315, AI synthesis 310, and generated samples 320 (also referred to as synthesized samples). The physical system 350 include a previous process 355, a target process 360, samples 365, and a next process 370. For ease of explanation, the workflow 300 is discussed in the context of a semiconductor wafer fabrication system but this is just one example of where the workflow 300 can be used. The system could be used in any physical manufacturing process where resulting devices (e.g., circuits or electronic devices such as smartphones, televisions, computers, etc.) are tested or evaluated.

For example, the previous process 355 may be one or more steps in the semiconductor fabrication process which can include deposition, etching, patterning (using masks), etc. The target process 360 can be a test process where images are captured on the semiconductor wafer, probe measurements are taken, and/or test signals are recorded. FIG. 3 illustrates transmitting physics constraints and input parameters to both the target process 360 and the AI synthesis 310. These constraints and input parameters can include the parameters or configurations of the test being performed by the target process 360 such as where to capture the images, where to probe the semiconductor wafer, what voltages/currents to use when testing the wafer, etc. Thus, in this example, the AI synthesis 310 in the digital twin 305 receives the same constraints and input parameters as the target process 360 in the physical system 350.

The target process 360 and the AI synthesis 310 can execute using the constraints and input parameters. The target process then generates the sample 365 that capture the results of the target process 360. For example, the samples 365 can include the captured images, probe measurements, or recorded testing signals generated from testing the semiconductor wafers.

In addition to using the constraints and parameters as inputs, the AI synthesis 310 also receives the reference real-world samples 315 as inputs. As shown, the reference real-world samples 315 are generated from the physical samples 365 generated by the physical target process 360. However, these reference real-world samples 315 are generated from past tests of previous semiconductor wafers. Stated differently, the real-world samples 315 are historical data generated by testing previous wafers.

The AI synthesis 310 uses the inputs to generate the synthesized samples 320. The samples 320 generated by the AI synthesis 310 are then combined with the samples 365 generated by the target process 360. As such, the generated samples 320 become real-world samples that can be used in the physical system 350.

Using AI synthesis in the digital twin 305 to generate supplemental samples that are combined with the samples 365 has several advantages. First, the target process 360 can be a less intensive testing process. For example, in previous solutions for testing wafers, the target process 360 may have tested the entire wafer. That is, the testing process may have captured images of the entire wafer, or probed the entire wafer to identify any faults in the wafer. With the workflow 300, the target process 360 may captures images of, or probe, only a few regions of the wafer. The generated samples 320 from the digital twin 305 of the wafer can then be used to generate samples for the remaining portions of the wafer. Thus, the target process, which typically takes much longer than performing AI synthesis 310, can be reduce in time and scope.

Second, testing wafers is expensive. Thus any techniques for reducing the time or equipment used for the test can result in substantial savings to the overall fabrication process.

In one embodiment, the next process 370 determines whether the wafer tested by the target process 360 has a fault. For example, the next process 370 can evaluate the combined samples generated by AI synthesis 310 and the target process 360 to predict whether the wafer has a fault. If so, the wafer may be tested thoroughly using a physical test to determine whether a fault actually exists. However, if the samples 365 indicate that the wafer likely does not have any faults then additional testing can be skipped. In this manner, the target process 360 can be a “light” testing process where the samples it generates are combined with the samples generated by the digital twin 305 to determine whether a “heavy” testing process should be performed by the next process 370. Wafers that pass the light testing can skip the heavy testing which can speed up the manufacturing process and save costs.

The workflow 300 is iterative, providing more samples for the physical system 350 while being guided by the physical system 350 and becoming a digital twin 305. The interaction could be with a single target process 360 or a combination of processes.

Further, the physical constraints and input parameters could change with time such as changes in design requirements, stricter quality expectations, new types of faults to analyze, and more. The generated samples 320 evolve when these changes are considered for the next iteration of sample synthesis. The generated samples 320 become the real-world samples which influence the next iteration of synthesis together with new real-world samples which, when available, can improve the quality of the generated samples 320. In this way, the real-world data insufficiency could be better addressed. The generated samples are continuously improved with the AI synthesis 310 guided by the real-world system in addition to just a few real-world data samples 365.

As a further non-limiting use case, assume the target process 360 is a test process which has class imbalance (insufficiency in fault class samples such as having too few samples that describe a fault condition). The synthetic fault samples generated by the AI synthesis 310 could address this situation and aid in building an AI model (not shown) as part of the next process 370 to predict whether a real-world sample is faulty (and the type of the fault) or not. This reduces the need for further costly physical testing of the unit corresponding to the real-world samples.

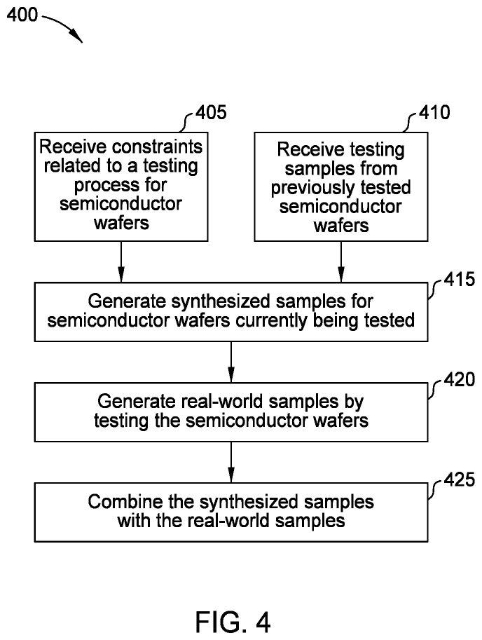

FIG. 4 is a flowchart of a method 400 for synthesizing samples using a digital twin for testing semiconductor wafers, according to an example. At block 405, AI synthesis in a digital twin (e.g., the AI synthesis 310 in FIG. 3) receives constraints related to a testing process for semiconductor wafers.

At block 410, the AI synthesis also receives testing samples from previously tested semiconductor wafers. These historical samples can be the reference real-world samples 315 in FIG. 3.

At block 415, the AI synthesis generates synthesized samples for a semiconductor wafer (or wafers) currently being tested.

At block 420, a physical testing process (e.g., the target process 360 in FIG. 3) generates real-world samples by testing the semiconductor wafer(s). For example, the semiconductor wafer may, in parallel, be tested using a physical testing process while the digital twin generates the synthesized samples.

At block 425, the synthesized samples generated by AI synthesis in the digital twin are combined with the real-world samples generated by the physical testing process.

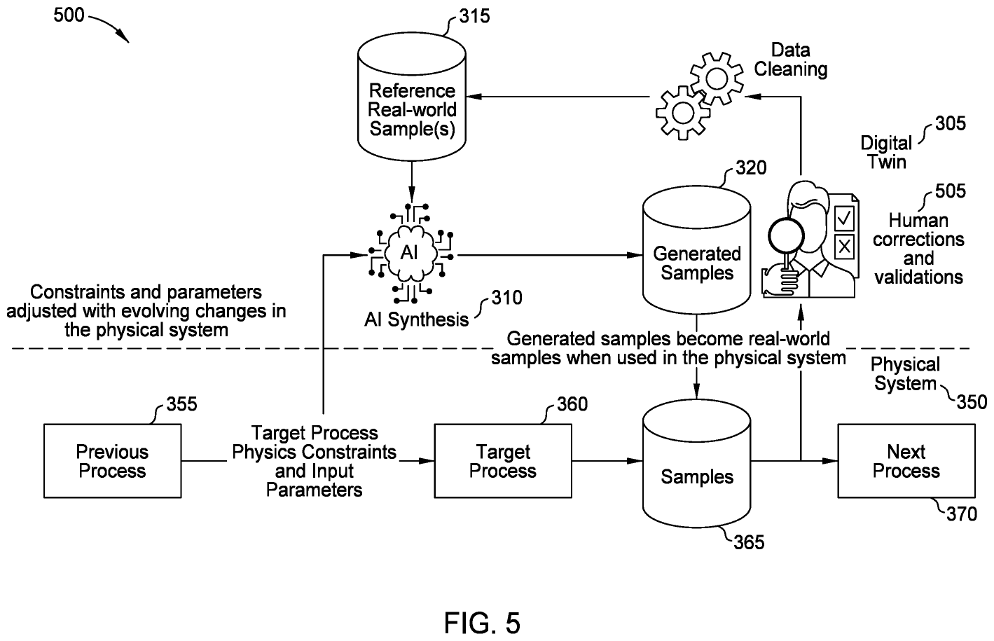

FIG. 5 illustrates a workflow 500 for synthesizing samples using a digital twin to combine with real-world samples, according to an example. The workflow 500 is the same as the workflow 300 except that the workflow 500 includes human corrections and validation stage 505. This stage 505 is performed before the samples 365 are stored as the reference real-world samples 315. At this stage 505, the data sample synthesis could be further refined by providing a human expert means to select synthesized samples from the samples 365. Synthesized samples can be clustered based on their similarities to form groups and provide visualization of the representative sample per cluster for the human expert to decide whether a sample cluster will be used as a reference real-world sample 315. That is, the human expert selects a subset of the clusters to use as the samples 315. Such a methodology gives more control for the human expert to guide the synthesis digital twin 305 towards a desired direction and speed up the synthesis process to achieve the expected data samples. For example, a human expert may be better at identifying images with faulty circuitry than an AI model. The human can identify clusters with more faulty circuitry and select only those clusters to be stored in as the real-world samples 315. This can help with class imbalance and guide the synthesis in a desired direction—e.g., generating synthesized samples more likely to have faulty circuitry.

FIG. 6 illustrates a workflow 600 for synthesizing design samples using a digital twin 605 to design an IC, according to an example. In this example, the workflow 600 is divided into the digital twin 605 and a physical system 650, where the digital twin 605 includes the components and data above the dotted line and the physical system 650 includes the components and data below the dotted line.

A brief discussion about designing ICs is now provided. In integrated circuit design, physical design is a step in the standard design cycle which follows after the circuit design. At this step, circuit representations of the components (devices and interconnects) of the design are converted into geometric representations of shapes which, when manufactured in the corresponding layers of materials, ensure the required functioning of the components. This geometric representation is called integrated circuit layout. This step is usually split into several sub-steps, which include both design and verification and validation of the layout.

Modern day IC design is split up into Front-end Design using hardware description languages (HDLs) and Back-end Design or Physical Design. The inputs to physical design are (i) a netlist, (ii) library information on the basic devices in the design, and (iii) a technology file containing the manufacturing constraints. Physical design is usually concluded by Layout Post Processing, in which amendments and additions to the chip layout are performed. This is followed by the Fabrication or Manufacturing Process where designs are transferred onto silicon dies which are then packaged into ICs.

Turning to FIG. 6, the digital twin 605 includes reference real-world design samples 615, AI design synthesis 610, and physical design samples 620 (also referred to as synthesized design samples). The physical system 650 include device analysis 655, identified faults 660, and manufacturing stage 665. For ease of explanation, the workflow 600 is discussed in the context of a designing an IC but this is just one example of where the workflow 600 can be used. The system could be used in any physical manufacturing process where resulting devices (e.g., circuits, an electronic device (e.g., smartphone, television, computer, etc.) are being designed.

The device analysis 655 receives as an input a designed chip (e.g., a historical chip that has already been manufactured) and current and voltages associated with that chip. The device analysis 655 then analyzes the designed chip to identify faults 660. For example, assume that a semiconductor company wants to design a new version of their processor (e.g., a central processing unit (CPU) or application specific integrated circuit (ASIC)). When the workflow 600 first begins, the designed chip can be the old version of the processor that is, e.g., currently being sold. The device analysis 655 can identify the faults 660 in the old version of this processor using, e.g., a physical testing process.

The AI design synthesis 610 receives the identified faults 660 as an input, along with an input circuit design—e.g., the design for the new version of the processor. The AI design synthesis 610 can also receive the physical design (e.g., the geometric layout) and the circuit design (e.g., a netlist or hardware description language (HDL)) of the old designed chip (e.g., the old version of the processor).

In addition to these inputs, the AI design synthesis 610 also receives reference real-world design samples 615 which correspond to past chip circuit and physical design. These circuits and designs may be from ICs that are different from the processor being designed, and may come from external sources such as an open standard. For example, the new version of the processor may have a new feature (e.g., a new circuit) that was not in the old version of the processor. However, this new feature may be in a different IC that was not manufactured by the company—e.g., could be in an open standard. The circuit and physical design from this IC can be used to populate the real-world design samples 615. This helps the AI design synthesis 610 to generate physical design samples 620 that are relevant to new circuitry in the input circuit design that may not have been in previous generations of the processor.

The physical design samples 620 can then be reviewed and validated by human corrections and validations 625 (e.g., a human expert). The validated design samples 620 can then be used in the manufacturing stage 665 to fabricate a physical IC. This can include fabricating multiple variants of the IC.

The workflow can then repeat (e.g., iterate) where the designed chip (e.g., a new version of the processor) fabricated in the manufacturing stage 665 is subjected to device analysis 655 to identify the faults 660. The faults are feed back into the AI design synthesis along with the other inputs to generate updated physical design samples 620 which can be used to manufacture the IC. This can repeat to further remove faults from the design, where the final physical design samples 620 are used to mass produce the new IC.

Advantageously, using the workflow 600 may mean less iterations (or less variants) are used to arrive at a final design of the IC. For example, where the digital twin 605 is not used, a manufacturer may generate 10 variants each iteration, but when the digital twin 605 is used, the manufacture may use only 2-3 variants each iteration. Further, it is difficult for humans to identify and resolve faults in the IC, but this is handled automatically by the AI design synthesis 610.

The workflow 600 illustrates the case of data insufficiency when designing a chip for a completely new purpose compared to the past chips designed (e.g., past versions of the chip). However, the new chip may have components and circuitry which are part of past chip designs. Hence, part of the new chip design could tap into the past designs represented by the reference real-world design samples 620. Using the workflow 600, the digital twin 605 can synthesize designs which have the least faults for different set parameters for the human desired hardware components.

FIG. 7 is a flowchart of a method 700 for synthesizing design samples using a digital twin to design an integrated circuit, according to an example. At block 705, AI synthesis in a digital twin receives faults from a previous IC (e.g., the identified faults 660 in FIG. 6). For example, the previous IC may be a previous version of the IC or device (e.g., a previous version of a processor or a GPU).

At block 710, AI synthesis receives a new IC design. For instance, this could be the design (e.g., a layout) for a new version of the IC (e.g., a newer version of the processor or GPU).

At block 715, AI synthesis receives a related IC design (e.g., the real-world design samples 615 in FIG. 6). For example, the related IC design may be for a specific circuit block in the new IC design. This circuit block may not have been in the previous version of the IC discussed at block 705. Or the related IC design may be for a different processor.

At block 720, AI synthesis generates synthesized design samples for the new IC (e.g., the physical design samples 620 in FIG. 6). The design samples can define a layout for the new IC.

At block 725, the new IC is manufactured (or fabricated) using the synthesize design samples. In one embodiment, the synthesized design samples may be defined multiple variants of the new IC.

At block 730, the new IC (and any variants) are analyzed to identify faults. Referring to FIG. 6, device analysis 655 can be performed to identify faults 660 in the new IC.

At block 735, the method 700 returns to block 720 where the faults are fed back into the AI synthesis to generate updated synthesized design samples for the new IC. The blocks 720, 725, and 730 can repeat any number of times.

FIG. 8 illustrates a workflow 800 for synthesizing samples using a digital twin using data from multiple domains, according to an example. The workflow 800 is the same as the workflow 300 except that the workflow 800 includes sample features 805 from a different domain. In some cases, features sampled from a first domain can improve the synthesis of data samples in a second, different domain by cross domain adaptation. Sample features of available real-world samples and the actual samples aid in generating the samples from the sample features which are in different domains.

Features of samples from a different domain (such as an Electrical computer-aided design (ECAD) diagram for a wafer substrate) are transformed to synthesize new samples in a different domain (such as physical substrate samples, which can be images of the wafer substrate). For example, the real-world samples 315 could include physical substrate samples (e.g., the second domain) while the sample features 805 could be ECAD diagrams. AI synthesis 310 combines the data from these two domains to synthesize physical substrate samples for the ECAD diagrams.

FIG. 9 is a flowchart of method 900 for synthesizing samples using a digital twin using data from multiple domains, according to an example. At block 905, AI synthesis receives constraints related to a target process (e.g., a real-world process). For example, the target process 360 in FIG. 8 may generate physical substrate samples from testing a semiconductor wafer.

At block 910, AI synthesis receives samples from a first domain. For example, the real-world samples 315 in FIG. 8 may be physical substrate samples generated by testing previous semiconductor wafers. That is, the real-world sample 315 can be historical data.

At block 915, AI synthesis receives samples from a second, different domain. For example, the sample features 805 can be a different type of data than the real-world samples 315, such as ECAD diagrams.

At block 920, AI synthesis generates synthesized samples for the first domain using the samples from both the first domain and the second domain and the contraints related to the target process. For example, the generated samples 320 in FIG. 8 can be physical substrate samples generated by the digital twin 810.

At block 925, the target process generates real-world samples for the first domain. That is, the samples 365 in FIG. 8 may be physical substrate samples generated from performing a physical test on the semiconductor wafer.

At block 930, the synthesized samples generated at block 920 are combined with the real-world samples generated at block 930. The combined samples can then be used to analyze the semiconductor in the next process 370 in FIG. 9.

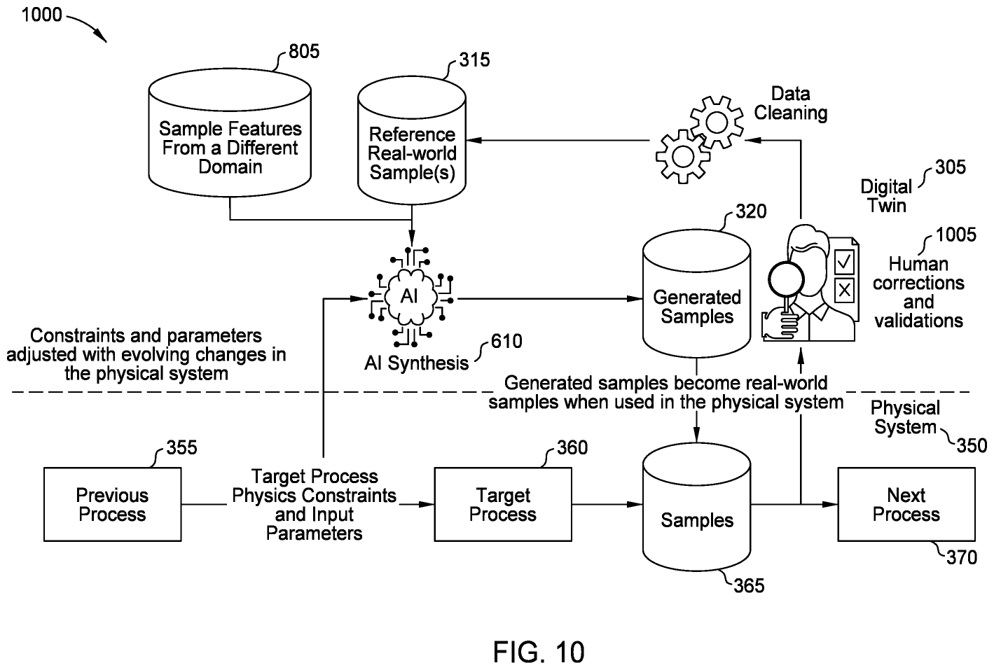

FIG. 10 illustrates a workflow 1000 for synthesizing samples using a digital twin using data from multiple domains, according to an example. The workflow 1000 is the same as the workflow 800 except that the workflow 1000 includes human corrections and validation stage 1005. This stage 1005 is performed before the samples 365 are stored as the reference real-world samples 315. At this stage 1005, the data sample synthesis could be further refined by providing a human expert means to select synthesized samples from the samples 365. Synthesized samples can be clustered based on their similarities to form groups and provide visualization of the representative sample per cluster for the human expert to decide whether a sample cluster will be used as a reference real-world sample. Such a methodology gives more control for the human expert to guide the synthesis digital twin 810 towards a desired direction and speed up the synthesis process to achieve the expected data samples. For example, a human expert may be better at identifying images with faulty circuitry than an AI model. The human can identify clusters with more faulty circuitry and select only those clusters to be stored in as the real-world samples 315. This can help with class imbalance and guide the synthesis in a desired direction—e.g., generating synthesized samples more likely to have faulty circuitry.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. A method comprising:
receiving, at a computing system, physics constraints related to a real-world process;
receiving, at the computing system, historical samples corresponding to previous iterations of the real-world process;
performing, using a digital twin at the computing system, artificial intelligence (AI) synthesis to generate synthesized samples for the real-world process based on the physics constraints and the historical samples;
performing the real-world process to generate real-world samples; and
combining the synthesized samples with the real-world samples.

2. The method of claim 1, wherein the real-world process is a process in at least one of semiconductor fabrication or manufacturing an electronic device.

3. The method of claim 1, wherein the real-world process comprises testing a semiconductor wafer to determine a fault, wherein the historical samples are generated by testing previous semiconductor wafers, wherein the physics constraints comprise testing parameters for testing the semiconductor wafer.

4. The method of claim 3, further comprising:
analyzing the combined synthesized samples and real-world samples to determine whether additional testing should be performed on the semiconductor wafer.

5. The method of claim 1, wherein data generated by the previous iterations of the real-world process is clustered into clusters, the method further comprising:
receiving a selection of a subset of the clusters to use as the historical samples.

6. The method of claim 1, further comprising:
receiving samples in a first domain, wherein the AI synthesis is performed using the samples in the first domain,
wherein the synthesized samples are in a second domain, wherein the first domain is a different data type than the second domain.

7. The method of claim 6, wherein the samples in the first domain comprises at least one of design diagrams of a semiconductor wafer and the synthesized samples comprises physical substrate samples of the semiconductor wafer.

8. A computer readable medium comprising instructions which, when executed by a processor in a computing system, perform an operation, the operation comprising:
receiving, at the computing system, physics constraints related to a real-world process;
receiving, at the computing system, historical samples corresponding to previous iterations of the real-world process;
performing, using a digital twin at the computing system, artificial intelligence (AI) synthesis to generate synthesized samples for the real-world process based on the physics constraints and the historical samples;
performing the real-world process to generate real-world samples; and
combining the synthesized samples with the real-world samples.

9. The computer readable medium of claim 8, wherein the real-world process is a process in at least one of semiconductor fabrication or manufacturing an electronic device.

10. The computer readable medium of claim 8, wherein the real-world process comprises testing a semiconductor wafer to determine a fault, wherein the historical samples are generated by testing previous semiconductor wafers, wherein the physics constraints comprise testing parameters for testing the semiconductor wafer.

11. The computer readable medium of claim 10, wherein the operation further comprises:
analyzing the combined synthesized samples and real-world samples to determine whether additional testing should be performed on the semiconductor wafer.

12. The computer readable medium of claim 8, wherein data generated by the previous iterations of the real-world process is clustered into clusters, the operation further comprising:
receiving a selection of a subset of the clusters to use as the historical samples.

13. The computer readable medium of claim 8, wherein the operation further comprises:
receiving samples in a first domain, wherein the AI synthesis is performed using the samples in the first domain,
wherein the synthesized samples are in a second domain, wherein the first domain is a different data type than the second domain.

14. The computer readable medium of claim 13, wherein the samples in the first domain comprises at least one of design diagrams of a semiconductor wafer and the synthesized samples comprises physical substrate samples of the semiconductor wafer.

15. A method comprising:
receiving, at a computing system, faults identified on a first integrated circuit (IC);
receiving, at the computing system, an IC design for a new IC; and
performing, using a digital twin at the computing system, artificial intelligence (AI) synthesis to generate synthesized design samples for the new IC based on the identified faults and the IC design.

16. The method of claim 15, further comprising:
manufacturing the new IC based on the synthesized design samples.

17. The method of claim 16, further comprising:
analyzing the new IC to identify faults; and
feeding back the identified faults for the new IC to the AI synthesis to generate updated synthesized design samples for the new IC; and
manufacturing the new IC based on the updated synthesized design samples.

18. The method of claim 17, wherein manufacturing the new IC based on the synthesized design samples comprising manufacturing different variants of the new IC, analyzing the different variants to identify faults, and feeding back the identified faults for the variants to generate the updated synthesized design samples for the new IC.

19. The method of claim 15, further comprising:
receiving, at the computing system, a related IC design, wherein the related IC design corresponds to a circuit block in the IC design for the new IC that is not in the first IC.

20. The method of claim 19, wherein the first IC is an older version of a device and the new IC is a newer version of the device, wherein the related IC design corresponds to a different device.
